(19) United States
(12) Patent Application Publication
(10) Pub. No.: US 2024/0195396 A1
(43) Pub. Date: Jun. 13, 2024

(54) COMPRESSING HIGH FREQUENCY EMISSIONS IN 10BASE-T1S DRIVER BY USING MULTIPLE STAGE NOTCH/BAND STOP FILTERING

(71) Applicant: Microchip Technology Incorporated, Chandler, AZ (US)

(72) Inventors: Jiachi Yu, Foshan (CN); Henry Liang, Shenzhen (CN); James Ho, Escondido, CA (US); Galin I. Ivanov, Stutensee (DE); Kevin Yang, Shenzhen (CN); Dixon Chen, Shenzhen (CN); Congqing Xiong, Shenzhen (CN); Hongming An, San Diego, CA (US)

(21) Appl. No.: 18/531,232

(22) Filed: Dec. 6, 2023

(30) Foreign Application Priority Data
Dec. 7, 2022 (CN) 202211564056.0

(51) Int. Cl. H03K 5/1252; H03K 19/20

(52) U.S. Cl. CPC H03K 5/1252; H03K 19/20; H03K 2005/00019

(57) ABSTRACT

Reducing emissions of predetermined frequencies using delay elements and related apparatuses, methods, and systems are disclosed. An apparatus includes an input terminal to receive a signal, delay elements electrically connected to the input terminal, an output terminal to provide a reduced slew rate signal, and combination circuitry electrically connected to the delay elements and the output terminal. The delay elements provide delayed signals responsive to the received signal. Respective ones of the delayed signals include delayed versions of the received signal. The combination circuitry combines the delayed signals to generate the reduced slew rate signal. Delays associated with the delay elements are chosen to reduce emissions of one or more predetermined frequencies of the reduced slew rate signal as compared to the received signal.

### CROSS-REFERENCE TO RELATED APPLICATIONS

This application claims the benefit of the filing date of Chinese Patent Application Serial No. 202211564056.0, filed Dec. 7, 2022, for “COMPRESSING HIGH FREQUENCY EMISSIONS IN 10BASE-T1S DRIVER BY USING MULTIPLE STAGE NOTCH/BAND STOP FILTERING,” the disclosure of which is incorporated herein in its entirety by this reference.

### TECHNICAL FIELD

This disclosure relates generally to reducing emissions of one or more predetermined frequencies of a reduced slew rate signal as compared to a received signal, and more specifically to reducing predetermined frequency emissions using delay elements.

### BACKGROUND

In some applications of wired local area networks (e.g., Ethernet), emission limits across various frequencies may be relatively stringent. For example, in vehicle wired local area networks, relatively stringent emission limits may be imposed at Frequency Modulated Broadcast Band (FM) and Digital Audio Broadcasting (DAB) frequencies.

Communication technology continues to gain in popularity worldwide. The proliferation of communication devices increases risk of interference between devices. To the extent that devices utilize the same or similar communication frequencies, interference may cause communication difficulties. Even harmonics outside of a device's designated communication frequency range may interfere with other devices communicating at different frequency ranges.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings, in which:

FIG. 1 is a block diagram of a variable delay driver, according to various examples;

FIG. 2 is a schematic illustration of a variable delay driver, which is an example of the variable delay driver of FIG. 1;

FIG. 3 is a schematic illustration of an example of a sub-driver of the variable delay driver of FIG. 1 or the variable delay driver of FIG. 2;

FIG. 4 is a schematic illustration of another example of a sub-driver of the variable delay driver of FIG. 1 or the variable delay driver of FIG. 2;

FIG. 5 is a flowchart illustrating a method of generating a reduced slew rate signal, according to various examples;

FIG. 6 is a flowchart illustrating a delay selecting method, according to various examples;

FIG. 7 is a block diagram of a filter including a series combination of three hypothetical first order notch filters;

FIG. 8 is a block diagram of a filter, which is equivalent to the filter of FIG. 7;

FIG. 9 is a response plot of an example of a frequency response, in decibels (dB), of the filter of FIG. 7 and the filter of FIG. 8;

FIG. 10 is a response plot of another example of a frequency response, in dB, of the filter of FIG. 7 and the filter of FIG. 8;

FIG. 11 is a block diagram of a portion of a wired local area network, according to various examples;

FIG. 12 is a schematic illustration of physical layer circuitry, which is an example of the PHY circuitry of the wired local area network of FIG. 11; and

FIG. 13 is a block diagram of a system, according to various examples.

### DETAILED DESCRIPTION

In the following detailed description, reference is made to the accompanying drawings, which form a part hereof, and in which are shown, by way of illustration, specific examples of examples in which the present disclosure may be practiced. These examples are described in sufficient detail to enable a person of ordinary skill in the art to practice the present disclosure. However, other examples enabled herein may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. In some instances, similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example of this disclosure to the specified components, steps, features, functions, or the like.

It will be readily understood that the components of the examples as generally described herein and illustrated in the drawings could be arranged and designed in a wide variety of different configurations. Thus, the following description of various examples is not intended to limit the scope of the present disclosure, but is merely representative of various examples. While the various aspects of the examples may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a digital signal processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, other structure, or combinations thereof. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

Device-to-device, device-to-transmission line, or transmission line-to-device interference during electrical communication (e.g., wireless communication or wired communication) may cause difficulty or failures in various communication environments. One example of a communication environment in which interference may pose a challenge is in vehicles. As used herein, the term “vehicle” refers to an automobile, a truck, a bus, a ship, or an aircraft. A “vehicle” may include a vehicle communication network. The complexity of a vehicle communication network may vary depending on a number of electronic devices within the network, and on other sources of electromagnetic radiation (e.g., amplitude modulated (AM) and frequency modulated (FM) radio, Digital Audio Broadcasting (DAB), and cellular telephone devices without limitation). For example, an advanced vehicle communication network may include various control modules for, for example, engine control, transmission control, safety control (e.g., antilock braking), and emissions control. To support these modules, the automotive industry relies on various communication protocols.

One example of a protocol that regulates single pair Ethernet communications in vehicles is 10BASE-T1S, or equivalently 10SPE, which is a network technology specified in IEEE 802.3cg™. Devices operating according to the 10BASE-T1S protocol should also meet the stringent high frequency emission test for automotive electronic devices. These stringent high frequency emission tests may be difficult to pass where frequencies of harmonic lobes for emissions from electronic devices used in vehicle networks may fall into some of the most stringently tested frequency ranges in these tests. By way of non-limiting examples, some of the most stringent requirements for these tests may fall within bandwidths designated for frequency modulated (FM) radio (substantially 87 to 108 megahertz (MHz)) and digital audio broadcast (DAB) (substantially 1100 MHz). Rise and fall shaping (e.g., cosine curve rise/fall shaping) may create emission lobes in the FM and DAB frequencies where the limit lines are especially stringent, which may create a problem in automotive use.

According to various examples, emissions in network communications (e.g., in the FM and DAB frequency ranges) may be compressed using multipole stage drivers implemented as notch filters or band stop filters. Driver emissions in the FM and DAB bands may be reduced by shaping the rise and fall of signal levels. This rise and fall shaping according to various examples may also be referred to herein as a “notch filter” because emissions are reduced in specific frequencies or ranges of frequencies. The high frequency emission spectrum (e.g., within the FM band, the DAB band, without limitation) with notch/stop band filtering may be reduced to meet the stringent emission requirement of automotive products. In some examples, multiple stages of driver cells may be designed with designated delay to shape the output waveform for low emission characteristics. The terms “frequency range,” “band,” “frequency band,” and “broadcast band” are used herein interchangeably to refer to ranges of frequencies.

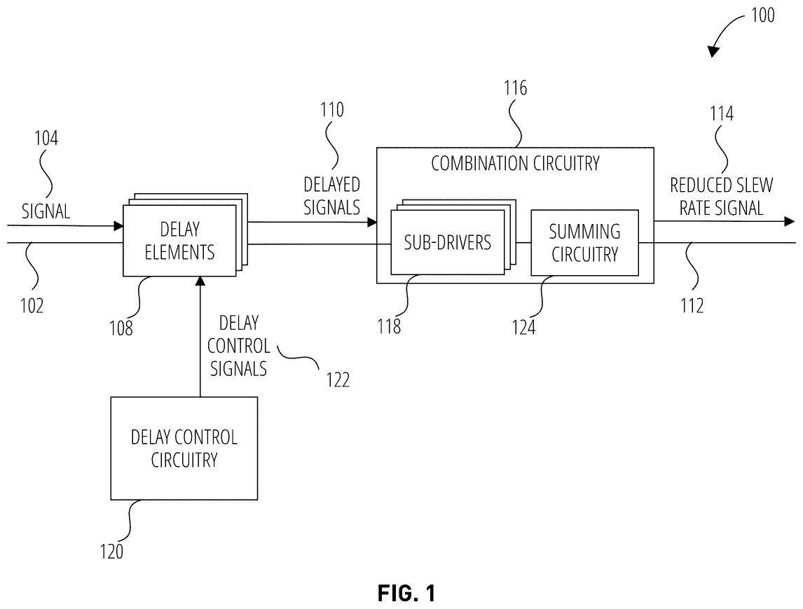

FIG. 1 is a block diagram of a variable delay driver 100, according to various examples. The variable delay driver 100 includes an input terminal 102, delay elements 108, an output terminal 112, and a combination circuitry 116. The input terminal 102 receives a signal 104. The delay elements 108 (e.g., arranged in a delay network, without limitation) are electrically connected to the input terminal 102. The delay elements 108 provide respective ones of delayed signals 110 responsive to the received signal 104. Respective ones of the delayed signals 110 include different delayed versions of the received signal 104. The output terminal 112 provides a reduced slew rate signal 114. The combination circuitry 116 is electrically connected to the delay elements 108 and the output terminal 112. The combination circuitry 116 combines the delayed signals 110 to generate the reduced slew rate signal 114. Delays associated with the delay elements 108 are chosen to reduce emissions of one or more predetermined frequencies of the reduced slew rate signal 114 as compared to the received signal 104.

The combination circuitry 116 includes sub-drivers 118. The sub-drivers 118 are “sub-drivers” in the sense that the variable delay driver 100 is a driver and the sub-drivers 118 are sub-drivers to the variable delay driver 100. At least some of the sub-drivers 118 are electrically connected from respective ones of the delay elements 108 to the output terminal 112 to drive respective ones of the delayed signals 110 to the output terminal 112. In some examples, one of the sub-drivers 118 is electrically connected from the input terminal 102 to the output terminal 112 (not shown).

In some examples the variable delay driver 100 includes delay control circuitry 120 electrically connected to the delay elements 108. The delay control circuitry 120 provides delay control signals 122 to the delay elements 108 to control the delays associated with the delay elements 108. Accordingly, in such examples, the delay elements 108 may have electrically controllable delay associated therewith, and the electrically controllable delay of the respective delay elements 108 is controlled responsive to the delay control signals 122.

As previously mentioned, emissions in network communications (e.g., in the FM and DAB frequency ranges) may be compressed using multipole stage drivers implemented as notch filters or band stop filters. The sub-drivers 118, in combination with the delay elements 108, may be these multipole stage drivers to implement a notch filter or band stop filter. Delays associated with the delay elements 108 are chosen to reduce emissions of one or more predetermined frequencies of the reduced slew rate signal 114 as compared to the received signal 104. A “notch filter” is thus implemented because emissions are reduced in specific frequencies or ranges of frequencies. In some examples, the one or more predetermined frequencies include three predetermined frequencies. In such examples the delay control circuitry 120 may determine three different preliminary delays associated with the three predetermined frequencies for three hypothetical first-order notch filters. The delay control circuitry 120 may also determine eight intermediate total delays associated with chaining the three hypothetical first-order notch filters together. The delay control circuitry 120 may sort the eight intermediate total delays in ascending order and determine seven delay differences by subtracting, for respective ones of the eight intermediate total delays except for a lowest intermediate delay, the intermediate total delays from immediately subsequent ones of the intermediate total delays. The delay control circuitry 120 may select the delays associated with the delay elements to be the respective delay differences.

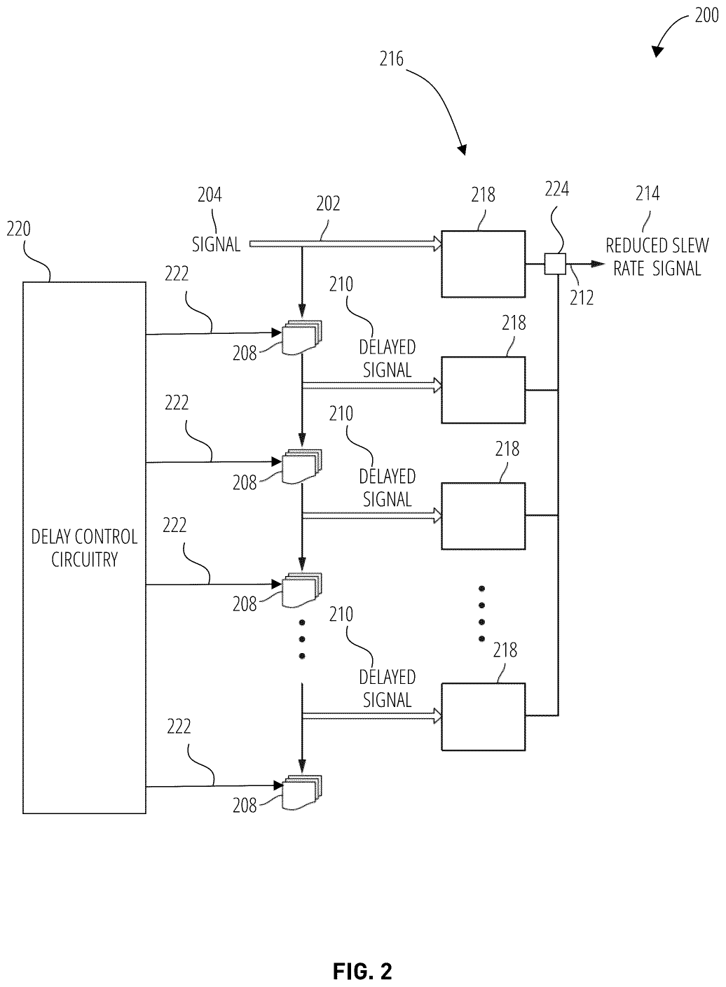

FIG. 2 is a schematic illustration of a variable delay driver 200, which is an example of the variable delay driver 100 of FIG. 1. The variable delay driver 200 includes sub-drivers 218 operably coupled in parallel between an input terminal 202 and an output terminal 212. The variable delay driver 200 also includes one or more delay elements 208 coupled between the input terminal 202 and one or more of the sub-drivers 218 to deliver a delayed version of a signal 204, illustrated as delayed signal 210, received at the input terminal 202, to at least two of the sub-drivers 218 at different points in time to control a slew rate of a reduced slew rate signal 214 at the output terminal 212. The delay elements 208 are electrically connected in series from the input terminal 202 to a last one of the delay elements 208.

The sub-drivers 218 are “sub-drivers” to the variable delay driver 200 in that the variable delay driver 200 is a driver and the sub-drivers 218 are sub-drivers to the variable delay driver 200. Respective ones of the sub-drivers 218 and their corresponding ones of the delay elements 208, if applicable (e.g., a first one of the sub-drivers 218 may not have a corresponding one of the delay elements 208, and is electrically connected from the input terminal 202 to the output terminal 212, without limitation), may be referred to as a “stage.” Accordingly, at least some of the sub-drivers 218 are connected between at least some of the delay elements 208 and the output terminal 212. A respective stage has a designated delay associated therewith. The respective outputs of the stages may be summed together by summing circuitry 224 to create the reduced slew rate signal 214. The combined output may have a desired spectrum with low emission at designated frequency bands.

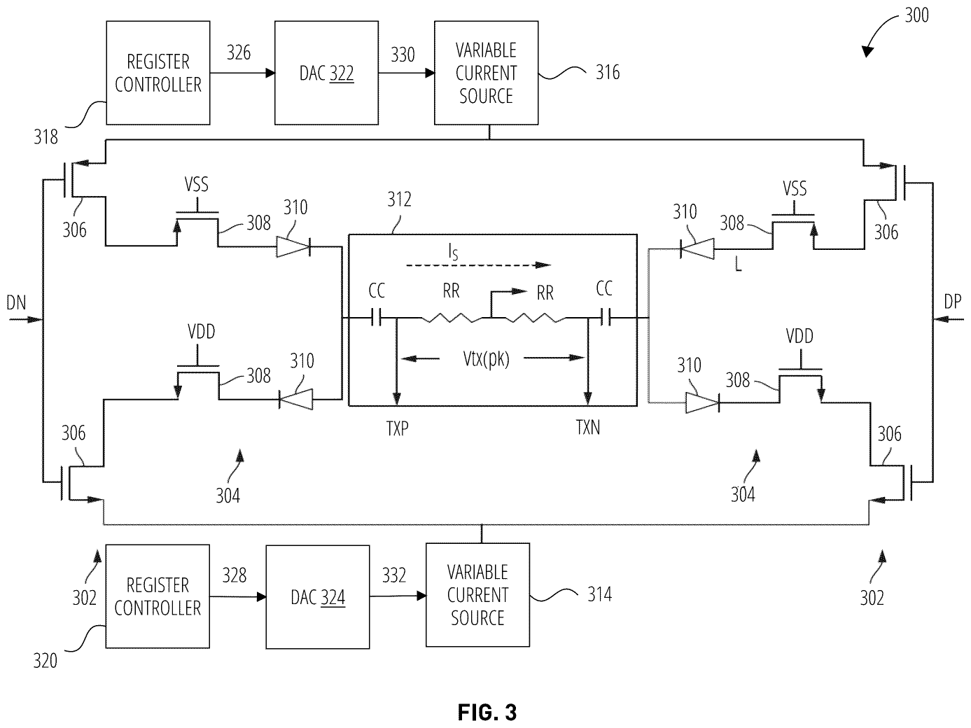

In the example illustrated in FIG. 2, respective ones of the delay elements 208 cause respective ones of the sub-drivers 218 to receive assertions (e.g., transitions from one logic voltage level to another, without limitation) of the signal 204 at a different point in time. As a result, at the output terminal 212, respective ones of the sub-drivers 218 will start to drive a new received bit at a staggered point in time relative to the others. This staggering in the driving of the reduced slew rate signal 214 results in a reduced slew rate as compared to a slew rate that would result from not staggering the driving. The reduced slew rate reduces higher-frequency components of the reduced slew rate signal 214 as compared to the signal 204, which have a tendency to result in EMI emissions. Consequently, the variable delay driver 200 results in lower EMI emissions as compared to drivers that do not use staggered driving. The use of stages, as in the variable delay driver 200 of FIG. 3, may also enable different delay and different current level control.

In some examples the variable delay driver 200 includes delay control circuitry 220 electrically connected to the delay elements 208. The delay control circuitry 220 provides delay control signals 222 to the delay elements 208 to control the respective delays associated with the respective delay elements 208. Accordingly, in such examples the delay elements 208 may have electrically controllable delay associated therewith, and the electrically controllable delay of the respective delay elements 208 is controlled responsive to the delay control signals 222.

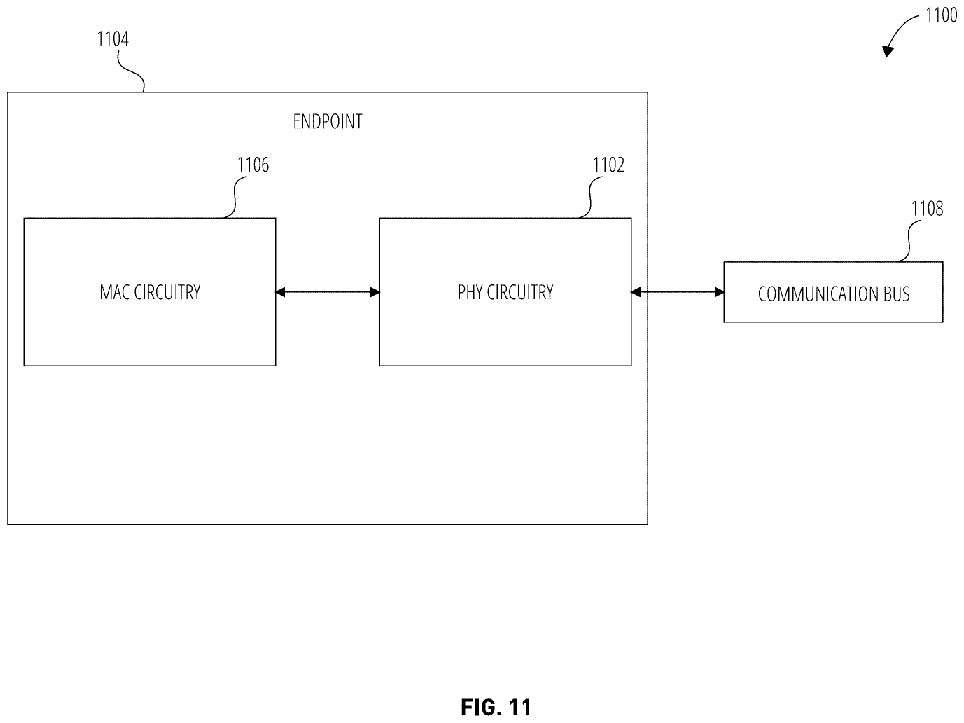

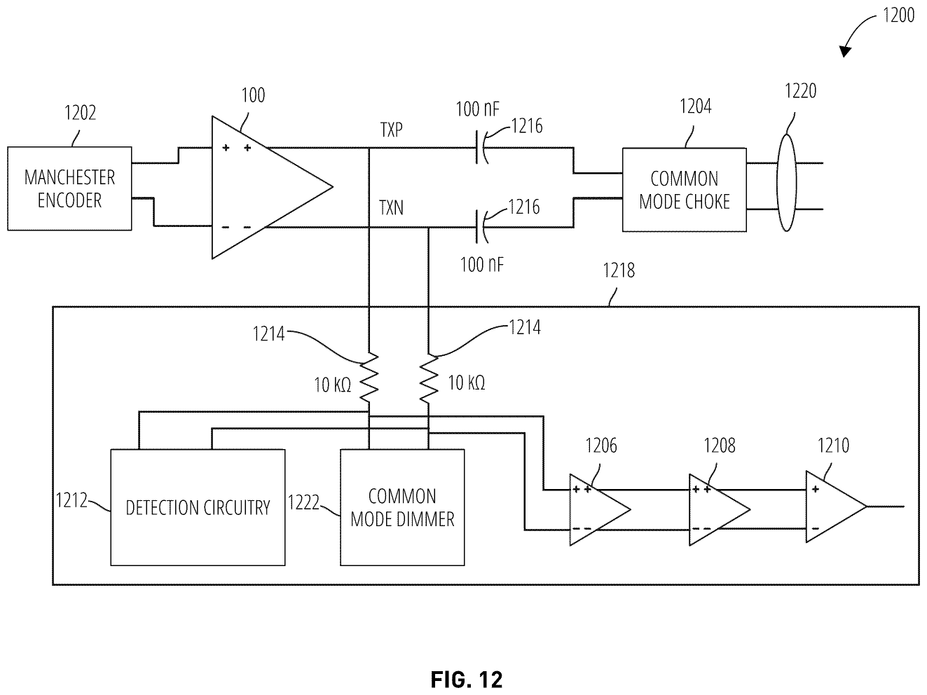

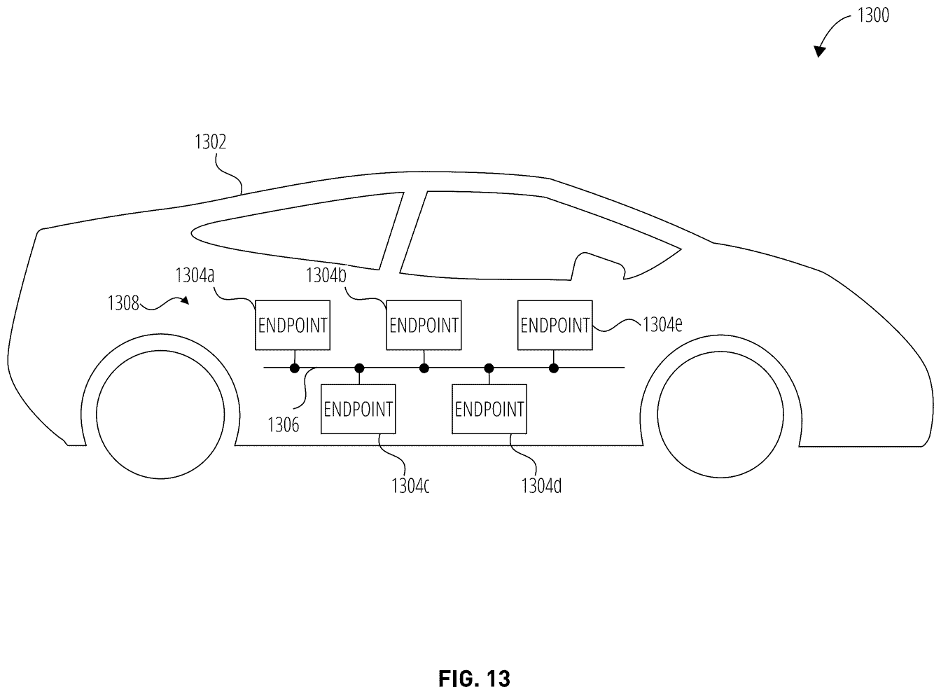

FIG. 3 is a schematic illustration of a sub-driver 300, which may be an example of a sub-driver 118 of the variable delay driver 100 of FIG. 1 or of a sub-driver 218 of the variable delay driver 200 of FIG. 2. As can be seen in FIG. 3, current in the sub-driver 300 is switched by differential data appearing at input terminals DN, DP. The sub-driver 300 protects the data and tolerates high common mode surges on a communication bus (e.g., the communication bus 1108 of FIG. 11, the communication bus 1220 of FIG. 12, or the shared transmission medium 1306 of FIG. 13, without limitation). The sub-driver 300 includes a high-speed input stage 302 and a high-voltage intermediate stage 304. The high-speed input stage 302 includes data switches including high-speed transistors 306, and the high-voltage intermediate stage 304 includes high-voltage transistors 308 respectively cascaded with the high-speed transistors 306 and protection diodes 310 respectively cascaded with the high-voltage transistors 308. As a result, the high-speed input stage 302 and the differential data, appearing at input terminals DN, DP are protected (e.g., the high-speed input stage 302 is protected against high common mode surges, and the differential data is protected against corruption due to malfunction of the high-speed input stage 302), and the sub-driver 300 can tolerate high common mode surges on the communication bus. In some examples, amplitude and slew rate of the output signal across output terminals TXP, TXN, are controlled by a digital to analog converter (DAC).

The sub-driver 300 may also include circuit components 312 including capacitors CC (e.g., 100 nF capacitors) in series with resistors RR (e.g., 25Ω resistors) between the capacitors CC. By way of non-limiting example, the circuit components 312 may be off-chip circuit components (e.g., discrete capacitors and resistors to be soldered to a printed circuit board). In operation, a current Is may pass through the capacitors CC and resistors RR. In some examples, a terminal between the resistors RR may be grounded (zero volts). As a result, a peak-to-peak voltage across output terminals TXP, TXN of the sub-driver 300 (e.g., measured across the resistors RR of the circuit components 312) may be given by Vtx(pk)=I_{S}*(50Ω), where RR=25Ω. In some examples, Is may vary from 2.5 milliAmps (mA) to 15 mA. By way of non-limiting example, where I_{S}=10 mA, Vtx(pk) may be about 1 Volt peak-to-peak (where the terminal between the resistors RR is grounded).

As Vtx(pk) is a function of the current I_{S}, an amplitude of the output of the sub-driver 300 may be controlled if I_{S} is controlled. As a result, the sub-driver 300 includes one or more variable current sources 314, 316 to control the current I_{S}. By way of non-limiting example, the variable current source 314 may include an NMOS variable current source and the variable current source 316 may include a PMOS variable current source. In some examples the variable current sources 314, 316 may be controlled by register controllers 320, 318, respectively. The register controllers 320, 318 may output voltage signals 328, 326, respectively, corresponding to desired voltage amplitude values for Vtx(pk) between output terminals TXP and TXN. In one example (not shown), output voltage signal 328, 326 may be provided to variable current sources 314, 316, respectively, to control the variable current sources 314, 316. The variable current sources 314, 316 conduct an appropriate current I_{S} to accomplish the desired voltage amplitude Vtx(pk) at the output terminals TXP, TXN. In examples where the variable current sources 314, 316 are controlled by analog inputs and the register controllers 320, 318, respectively, provide digital voltage signals 328, 326, respectively, the sub-driver 300 may include one or more Digital to Analog Converters (DACs) 324, 322. The DACs 324, 322 convert the respective voltage signals 328, 326 to respective analog voltage signals 332, 330, which are provided to the variable current sources 314, 316, respectively. By way of non-limiting example, the register controllers 320, 318 may control the variable current sources 314, 316 with three bit voltage signals 328, 326 corresponding to eight or less different voltage amplitude levels for Vtx(pk). In a specific, non-limiting example, the voltage signals 328, 326 may selectively indicate 250 mV, 500 mV, 750 mV, 1V, 1.25 V, or 1.5 V.

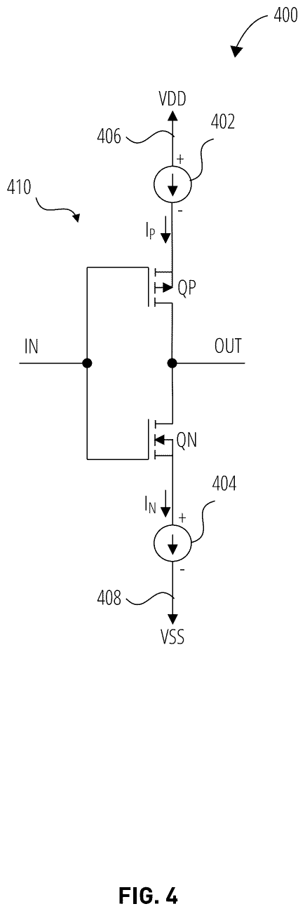

FIG. 4 is a schematic illustration of another example of a sub-driver 400 of the variable delay driver 100 of FIG. 1 or the variable delay driver 200 of FIG. 2. The sub-driver 400 includes a pull-up current source 402 electrically connected to a power supply high voltage potential node 406 (e.g., a VDD node, without limitation). The sub-driver 400 also includes a pull-down current source 404 electrically connected to a power supply low voltage potential node 408 (e.g., a VSS node). The sub-driver 400 includes a complementary metal oxide semiconductor (CMOS) inverter (CMOS inverter 410) electrically connected from the pull-up current source 402 to the pull-down current source 404. A pull-up current I_{P} is supplied by the pull-up current source 402 and is substantially the same as a pull-down current I_{N} supplied by the pull-down current source 404.

The CMOS inverter 410 includes a pull-up transistor QP and a pull-down transistor QN. A first terminal of the pull-up transistor QP is electrically connected to the positive lead of pull-up current source 402. A second terminal of the pull-up transistor QP is electrically connected to a second terminal of the pull-down transistor QN. A first terminal of the pull-down transistor QN is electrically connected to the negative lead of pull-down current source 404. Gate terminals of the pull-up transistor QP and the pull-down transistor QN are electrically connected to an input node IN of the CMOS inverter 410. The second terminals of the pull-up transistor QP and the pull-down transistor QN are electrically connected to an output node OUT of the CMOS inverter 410.

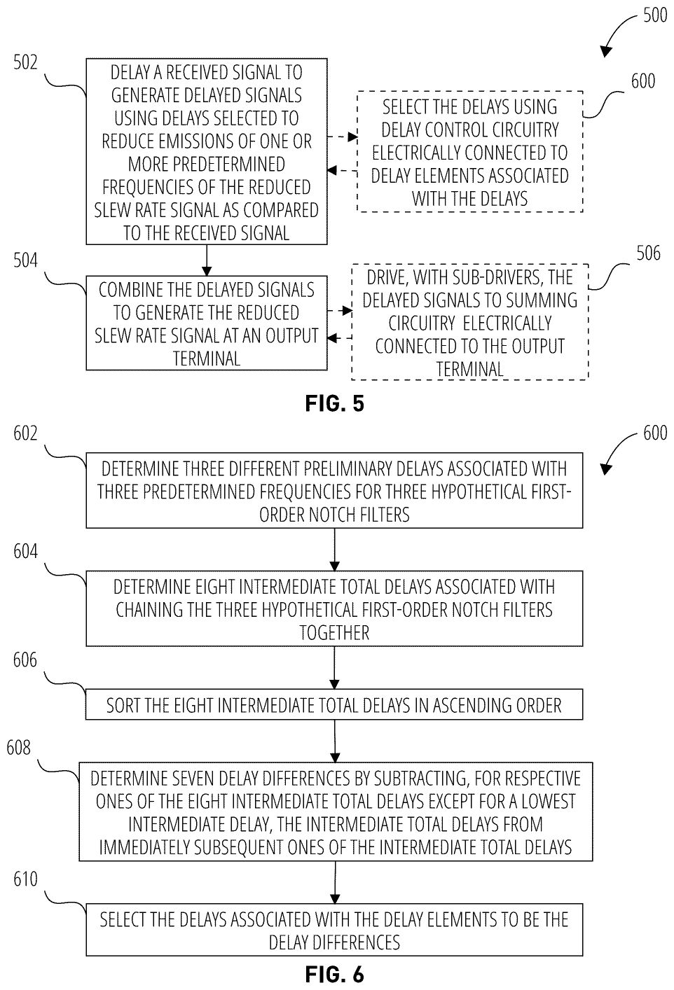

FIG. 5 is a flowchart illustrating a method 500 of generating a reduced slew rate signal (e.g., the reduced slew rate signal 114 of FIG. 1, the reduced slew rate signal 214 of FIG. 2, without limitation), according to various examples. At operation 502 the method 500 includes delaying a received signal (e.g., the signal 104 of FIG. 1, the signal 204 of FIG. 2, without limitation) to generate delayed signals (e.g., the delayed signals 110 of FIG. 1, the delayed signals 210 of FIG. 2, without limitation) using delays chosen to reduce emissions of one or more predetermined frequencies of the reduced slew rate signal as compared to the received signal. In some examples delaying the received signal includes, at delay selecting method 600, selecting the delays using control circuitry electrically connected to the delay elements associated with the delays. More detail regarding the delay selecting method 600 will be discussed below with reference to FIG. 6.

At operation 504 the method 500 includes combining the delayed signals to generate the reduced slew rate signal at an output terminal (e.g., the output terminal 112 of FIG. 1, the output terminal 212 of FIG. 2, without limitation). In some examples, combining the delayed signals includes, at operation 506, driving, with sub-drivers (e.g., the sub-drivers 118 of FIG. 1, the sub-drivers 218 of FIG. 2, without limitation), the delayed signals to summing circuitry (e.g., the summing circuitry 124 of FIG. 1, the summing circuitry 224 of FIG. 2, without limitation) electrically connected to the output terminal.

FIG. 6 is a flowchart illustrating a delay selecting method 600, according to various examples. The delay selecting method 600 is specifically designed to select delays for a variable delay driver including eight sub-drivers and seven delay elements. It should be appreciated that a different delay selecting method may be used with a variable delay driver including different numbers of sub-drivers and delay elements.

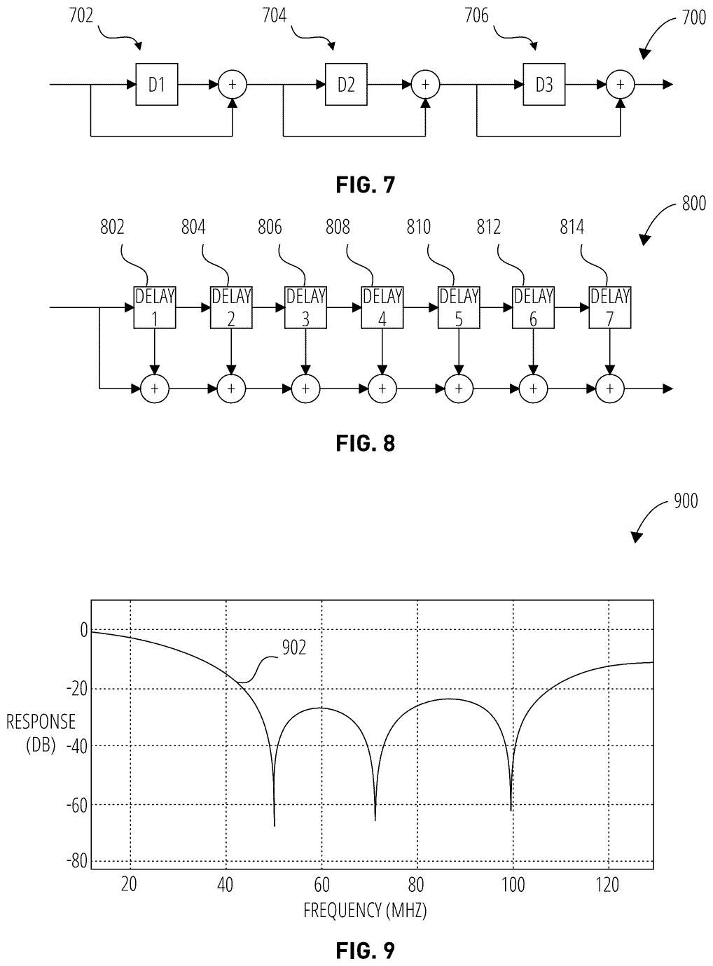

At operation 602 the delay selecting method 600 includes determining three different preliminary delays associated with three predetermined frequencies for three hypothetical first-order notch filters (702, 704, and 706 in FIG. 7). The variable delay driver including eight sub-drivers and seven delay elements may be modeled as a series combination of three first-order notch filters, respectively having a preliminary delay D1, D2, and D3, respectively, associated therewith. More detail regarding the series combination of first-order notch filters is discussed with reference to FIG. 7.

FIG. 7 is a block diagram of a filter 700 including a series combination of three hypothetical first-order notch filters 702, 704, and 706. A preliminary delay associated with hypothetical first-order notch filter 702 is D1, a preliminary delay associated with hypothetical first-order notch filter 704 is D2, and a preliminary delay associated with hypothetical first-order notch filter 706 is D3.

Respective preliminary delays D1, D2, D3 may be determined as a function of a desired notch frequency for the variable delay driver. For example, respective preliminary delays D1, D2, D3 may be determined as one half divided by a desired notch frequency for the variable delay driver. Accordingly, in some examples the preliminary delays D1, D2, D3 may be determined as:

$$D 1 = \frac{0.5}{f 1} \\ D 2 = \frac{0.5}{f 2} \\ D 3 = \frac{0.5}{f 3} ,$$

where f1, f2, and f3 are desired notch frequencies corresponding to preliminary delays D1, D2, and D3, respectively. A frequency response of the filter 700 is given by:

Dout=(1+z^{-D1})(1+z^{-D2})(1+z^{-D3}).

Referring again to FIG. 6, at operation 604 the delay selecting method 600 includes determining eight intermediate total delays associated with chaining the three hypothetical first-order notch filters 702, 704, and 706 (FIG. 7) together. The eight intermediate total delays may be determined by multiplying out the parentheticals in the above equation for Dout, which gives:

Dout=(1+z^{-D1}+z^{-D2}+z^{-D3}+z^{-(D1+D2)}+z^{-(D2+D3)}+z^{-(D1+D3)}+z^{-(D1+D2+D3)})

The eight intermediate total delays may be a negative of the exponents of respective added elements in this second equation for Dout, or namely [0, D1, D2, D3, D1+D2, D2+D3, D1+D3, D1+D2+D3].

At operation 606 the delay selecting method 600 includes sorting the eight intermediate total delays in ascending order. For example, the eight intermediate total delays [0, D1, D2, D3, D1+D2, D2+D3, D1+D3, D1+D2+D3] may be sorted in ascending order as [0, S1, S2, S3, S4, S5, S6, S7], where S1, S2, S3, S4, S5, S6, and S7 are the ascendingly ordered D1, D2, D3, D1+D2, D2+D3, D1+D3, and D1+D2+D3. For example, S1 is the smallest one of D1, D2, D3, D1+D2, D2+D3, D1+D3, and D1+D2+D3. S2 is the second smallest one of D1, D2, D3, D1+D2, D2+D3, D1+D3, and D1+D2+D3, and S7 is the largest one of D1, D2, D3, D1+D2, D2+D3, D1+D3, and D1+D2+D3.

At operation 608 the delay selecting method 600 includes determining seven delay differences by subtracting, for respective ones of the eight intermediate total delays except for a lowest intermediate delay, the intermediate total delays from immediately subsequent ones of the intermediate total delays. These seven delay differences, [DELAY 1, DELAY 2, DELAY 3, DELAY 4, DELAY 5, DELAY 6, DELAY 7], may be determined as follows:

DELAY 1=S1−0

DELAY 2=S2−S1

DELAY 3=S3−S2

DELAY 5=S5−S4

DELAY 6=S6−S5

DELAY 7=S7−S6

At operation 610 the delay selecting method 600 includes selecting the delays associated with delay elements (e.g., the delay elements 108 of FIG. 1, the delay elements 208 of FIG. 2, without limitation) to be the delay differences [DELAY 1, DELAY 2, DELAY 3, DELAY 4, DELAY 5, DELAY 6, DELAY 7]. As discussed with reference to the delay selecting method 600 in FIG. 5, selecting the delays associated with the delay elements to be the delay differences (operation 610) may include selecting the delays using delay control circuitry electrically connected to delay elements associated with the delays.

FIG. 8 is a block diagram of a filter 800, which is equivalent to the filter 700 of FIG. 7. The filter 800 includes delay elements 802, 804, 806, 808, 810, 812, and 814. A delay associated with delay element 802 is chosen to be delay difference DELAY 1. A delay associated with delay element 804 is chosen to be delay difference DELAY 2. A delay associated with delay element 806 is chosen to be delay difference DELAY 3. A delay associated with delay element 808 is chosen to be delay difference DELAY 4. A delay associated with delay element 810 is chosen to be delay difference DELAY 5. A delay associated with delay element 812 is chosen to be delay difference DELAY 6. Finally, a delay associated with delay element 814 is chosen to be delay difference DELAY 7.

FIG. 9 is a response plot 900 of an example of a frequency response 902, in decibels (dB), of the filter 700 of FIG. 7 and the filter 800 of FIG. 8. In the example illustrated in FIG. 9, the desired notch frequencies were 50 MHz, 72 MHz, and 100 MHz, corresponding to preliminary delays of D1=10 ns, D2=7 ns, and D3=5 ns. The corresponding ascending order sorted intermediate total delays are [0, 5, 7, 10, 12, 15, 17, and 22], which correspond to delay differences of [5, 2, 3, 2, 3, 2, 5]. The frequency response 902 illustrated in the response plot 900 of FIG. 9, therefore, is the result of using [5, 2, 3, 2, 3, 2, 5] for DELAY 1, DELAY 2, DELAY 3, DELAY 4, DELAY 5, DELAY 6, and DELAY 7 for the delay elements 802, 804, 806, 808, 810, 812, and 814, respectively, of the filter 800 of FIG. 8. As may be seen in the response plot 900, notches are located at about 50 MHz, 72 MHz, and 100 MHz. Accordingly, a variable delay driver (e.g., the variable delay driver 100 of FIG. 1, the variable delay driver 200 of FIG. 2, without limitation) implemented similarly to the filter 800 with the above discussed delays used for the delay elements will filter out emissions at and around 50 MHz, 72 MHz, and 100 MHz.

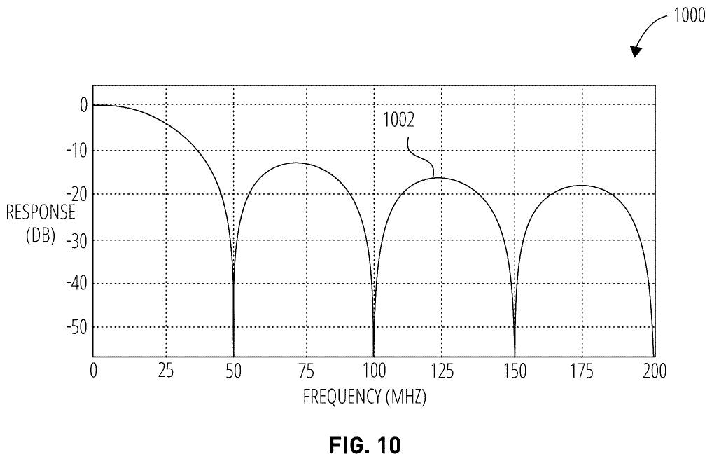

FIG. 10 is a response plot 1000 of another example of a frequency response 1002, in decibels (dB), of the filter 700 of FIG. 7 and the filter 800 of FIG. 8. In the example illustrated in FIG. 10, the desired notch frequencies were 50 MHz, 100 MHz, and 200 MHz, corresponding to preliminary delays of D1=10 ns, D2=5 ns, and D3=2.5 ns. The corresponding ascending order sorted intermediate total delays are [2.5, 5, 7.5, 10, 12.5, 15, 17.5, 20], which correspond to delay differences of [2.5, 2.5, 2.5, 2.5, 2.5, 2, 5]. The frequency response 1002 illustrated in the response plot 1000 of FIG. 10, therefore, is the result of using [2.5, 2.5, 2.5, 2.5, 2.5, 2, 5] for DELAY 1, DELAY 2, DELAY 3, DELAY 4, DELAY 5, DELAY 6, and DELAY 7 for the delay elements 802, 804, 806, 808, 810, 812, and 814, respectively, of the filter 800 of FIG. 8. As may be seen in the response plot 1000, notches are located at about 50 MHz, 100 MHz, and 200 MHz. Accordingly, a variable delay driver (e.g., the variable delay driver 100 of FIG. 1, the variable delay driver 200 of FIG. 2, without limitation) implemented similarly to the filter 800 with the above discussed delays used for the delay elements will filter out emissions at and around 50 MHz, 100 MHz, and 200 MHz.

FIG. 11 is a block diagram of a portion of a wired local area network 1100, according to various examples. The wired local area network 1100 includes an endpoint 1104 operably coupled to a communication bus 1108. The communication bus 1108 includes a shared transmission medium (e.g., a single twisted pair, without limitation) of the wired local area network 1100. As used herein, the term “shared transmission medium” refers to a wired transmission medium, such as a single twisted pair, that conducts both transmit signals and receive signals over the same conductive structure (e.g., wires, without limitation) for multiple endpoints similar to the endpoint 1104. By way of non-limiting example, endpoints in the wired local area network 1100 may all send and receive signals via the same shared transmission line (e.g., a single twisted pair, without limitation). The endpoint 1104 is to communicate via the communication bus 1108. While electrically connected to the communication bus 1108, the endpoint 1104 functions as a node of the wired local area network 1100.

The endpoint 1104 includes physical layer circuitry 1102 (PHY circuitry 1102) operably coupled to media access control (MAC) circuitry 1106 and the communication bus 1108. The PHY circuitry 1102 serves as an interface for a physical connection between the MAC circuitry 1106 and the communication bus 1108. In some examples the PHY circuitry 1102 includes at least a portion of Ethernet physical layer circuitry.

The wired local area network 1100 may be used in an automotive environment in some examples, such as that illustrated in FIG. 13. By way of non-limiting example, the wired local area network 1100 may be to connect one or more sensors in a vehicle to a computer or controller via a shared transmission medium, e.g., communication bus 1108. The one or more sensors and the computer or controller may respectively operate as endpoints, such as the endpoint 1104 of FIG. 11, in the wired local area network 1100.

FIG. 12 is a schematic illustration of physical layer circuitry 1200, which is an example of the PHY circuitry 1102 of the wired local area network 1100 of FIG. 11. The PHY circuitry 1200 includes transmitter circuitry including: a Manchester encoder 1202, the variable delay driver 100 of FIG. 1, and interference/noise compensation circuitry including capacitors 1216 (e.g., 100 nanoFarad (nF) capacitors) and common mode choke 1204. PHY circuitry 1102 includes receiver circuitry 1218 including detection circuitry 1212, receive amplifiers 1206, 1208, 1210 and interference/noise compensation circuitry including a common mode dimmer 1222, and resistors 1214 (e.g., 10 kiloOhm (kΩ) resistors). The transmitter circuitry and the receiver circuitry 1218 are both connected to the same communication bus 1220. As a result, the communication bus 1220 may be used for both transmitting and receiving data. In some examples, the communication bus 1220 may be a shared transmission medium (e.g., a single twisted pair (e.g., an Unshielded Twisted Pair, or UTP, without limitation), without limitation) of a wired local area network such as the wired local area network 1100 of FIG. 11.

The variable delay driver 100 drives signals provided to the variable delay driver 100 by the Manchester encoder 1202 to differential outputs TXP, TXN of the variable delay driver 100. The variable delay driver 100 also controls a slew rate and an amplitude (e.g., different output swing levels, without limitation) of a driver output of the variable delay driver 100. The variable delay driver 100 also tolerates high interference (e.g., common mode interference on the order of +/−40 volts or more, without limitation) and noise received through the communication bus 1220 at a driver output of the variable delay driver 100. The variable delay driver 100 also protects itself from high input voltage at a driver input of the variable delay driver 100. In addition, the variable delay driver 100 may filter out EMI at predetermined frequencies (e.g., frequencies associated with FM radio and DAB, without limitation) using the method 500 of FIG. 5.

Since the standards for EMI emissions in automobiles are relatively stringent, the slew rate of the driver output of the variable delay driver 100 may be decreased to reduce high-frequency components of a driven transmit signal provided at the driver output of the variable delay driver 100. The reduction of high-frequency components in the driven transmit signal at the driver output may result in reduced overall emissions of the physical layer circuitry 1200. Also, the interference/noise tolerance and input voltage protection enable the variable delay driver 100 to operate in the noisy and interference prone environment of an automobile. In addition, the filtering out of frequencies such as those corresponding to FM radio and DAB make the variable delay driver 100 suitable for the automotive environment.

Since the standards for EMI emissions in automobiles are relatively stringent at particular frequency ranges (e.g., those designated for FM radio and DAB, without limitation), delays in the delay elements (e.g., delay elements 108 of FIG. 1, delay elements 208 of FIG. 2, without limitation) may be chosen to implement a notch filter to filter out these specific frequencies or frequency ranges of interest. By way of non-limiting example, the delays of the delay elements may be chosen to target a notch frequency of a notch filter for an FM frequency in a frequency range of substantially 87 to 108 MHz. Also by way of non-limiting example, the delays of the delay elements may be chosen to target a notch frequency of substantially 100 MHz. As another non-limiting example, the delays of the delay elements may be chosen to target a notch frequency of a notch filter for a frequency of substantially 72 MHz. As yet another non-limiting example, the delays of the delay elements may be chosen to target a notch frequency of a notch filter for a frequency of substantially 50 MHz. As another non-limiting example, the delays of the delay elements may be chosen to target a notch frequency of a notch filter for one or more operating frequencies of one or more devices operating in a vehicle such as a vehicle 1302 of FIG. 13. More detail regarding the variable delay driver 100 is discussed with reference to FIG. 1 and FIG. 2.

The common mode dimmer 1222 protects sensitive receive circuitry (e.g., the detection circuitry 1212 and the receive amplifiers 1206, 1208, 1210) from interference (e.g., common mode interference) and noise received from the communication bus 1220 during Bulk Current Injection (BCI) conditions. For example, the common mode dimmer 1222 draws sufficient current through the resistors 1214 to remove dangerously high common mode interference and cause a voltage of signals received through the communication bus 1220 to drop to a safe level at the receiver circuitry 1218. By way of non-limiting example, the common mode dimmer 1222 may maintain the voltage of signals reaching the receiver circuitry 1218 to remain lower than a high power rail of the receiver circuitry 1218 (e.g., 3.3 V). The common mode dimmer 1222 enables the use of high gain receivers (e.g., receive amplifiers 1206, 1208, 1210) and signal/pulse/collision detectors (e.g., detection circuitry 1212) in the receiver circuitry 1218, filters out common mode interference signals, and results in low jitter and low power expenditure. In some examples, the common mode dimmer 1222 may be used for low power applications.

The detection circuitry 1212 may include signal detect circuitry, reflection detect circuitry, sleep mode detect circuitry, collision detect circuitry, other circuitry, or combinations thereof. The detection circuitry 1212 may detect signals received through the communication bus 1220. The detection circuitry 1212 (e.g., using reflection detect circuitry, without limitation) may diagnose the communication bus 1220 (e.g., by detecting short circuits, open circuits, other issues, or combinations thereof on the communication bus 1220). The detection circuitry 1212 (e.g., using sleep mode detect circuitry, without limitation) may trigger the receiver circuitry 1218 to sleep or wake up responsive to sleep or wake messages received via the communication bus 1220. The detection circuitry 1212 (e.g., using collision detect circuitry, without limitation) may detect signal collisions on the communication bus 1220. Signal and activity detection may also be implemented by the detection circuitry 1212.

To provide additional interference/noise protection, the common mode choke 1204 reduces (e.g., suppress) common mode interference received through the communication bus 1220, and the capacitors 1216 filter out direct current (DC) components of signals received from the communication bus 1220.

FIG. 13 is a block diagram of a system 1300, according to various examples. The system 1300 includes a vehicle 1302, which includes a shared transmission medium 1306 of a wired local area network 1308. The wired local area network 1308 may be an example of the wired local area network 1100 of FIG. 11. The vehicle 1302 also includes endpoints 1304a-1304e electrically connected to the shared transmission medium 1306. At least one of the endpoints may be the endpoint 1104 of FIG. 11, which as discussed above, may include the physical layer circuitry 1200 of FIG. 12. Accordingly, one or more of the endpoints 1304a-1304e may include an encoder (e.g., the Manchester encoder 1202 of FIG. 12, without limitation) to provide a signal to be transmitted to the wired local area network 1308 via the shared transmission medium 1306.

Also, one or more of the endpoints 1304a-1304e may include a variable delay driver (e.g., the variable delay driver 100 of FIG. 1, the variable delay driver 200 of FIG. 2, without limitation). As discussed above, a variable delay driver may include an input terminal (e.g., the input terminal 102 of FIG. 1, the input terminal 202 of FIG. 2, without limitation), delay elements (e.g., the delay elements 108 of FIG. 1, the delay elements 208 of FIG. 2, without limitation), combination circuitry (e.g., the combination circuitry 116 of FIG. 1, the combination circuitry 216 of FIG. 2, without limitation), and an output terminal (e.g., the output terminal 112 of FIG. 1, the output terminal 212 of FIG. 2, without limitation). The input terminal receives the signal from the encoder. The delay elements generate delayed signals responsive to the received signal. Delays associated with respective ones of the delay elements are chosen to reduce emissions of one or more predetermined frequencies of a reduced slew rate signal as compared to the received signal. The combination circuitry combines the delayed signals to generate the reduced slew rate signal. The output terminal is electrically connected to the shared transmission medium. The output terminal delivers the reduced slew rate signal to the shared transmission medium 1306.

### Examples

A non-exhaustive, non-limiting list of example embodiments follows. Not each of the example embodiments listed below are explicitly and individually indicated as being combinable with all others of the example embodiments listed below and embodiments discussed above. It is intended, however, that these example embodiments are combinable with all other example embodiments and embodiments discussed above unless it would be apparent to one of ordinary skill in the art that the embodiments are not combinable.

Example 1: An apparatus, comprising: an input terminal to receive a signal; delay elements electrically connected to the input terminal, the delay elements to provide delayed signals responsive to the received signal, respective delayed signals including delayed versions of the received signal; an output terminal to provide a reduced slew rate signal; and combination circuitry electrically connected to the delay elements and the output terminal, the combination circuitry to combine the delayed signals to generate the reduced slew rate signal, delays associated with the delay elements chosen to reduce emissions of one or more predetermined frequencies of the reduced slew rate signal as compared to the received signal.

Example 2: The apparatus of Example 1, wherein the combination circuitry includes sub-drivers, at least some of the sub-drivers electrically connected to drive respective ones of the delayed signals to the output terminal.

Example 3: The apparatus of Example 2, wherein one of the sub-drivers is electrically connected from the input terminal to the output terminal.

Example 4: The apparatus according to any one of Examples 2 and 3, wherein at least one of the sub-drivers includes: a pull-up current source electrically connected to a power supply high voltage potential node; a pull-down current source electrically connected to a power supply low voltage potential node; and a complementary metal oxide semiconductor (CMOS) inverter electrically connected from the pull-up current source to the pull-down current source.

Example 5: The apparatus of Example 4, wherein a pull-up current supplied by the pull-up current source is substantially the same as a pull-down current supplied by the pull-down current source.

Example 6: The apparatus according to any one of Examples 1-5, wherein the combination circuitry includes summing circuitry to combine the delayed signals by adding the delayed signals.

Example 7: The apparatus according to any one of Examples 1-6, comprising delay control circuitry electrically connected to the delay elements, the delay control circuitry to provide delay control signals to the delay elements to control the delays associated with the delay elements.

Example 8: The apparatus of Example 7, wherein: the one or more predetermined frequencies include three predetermined frequencies; and the delay control circuitry to: determine three different preliminary delays associated with the three predetermined frequencies for three hypothetical first-order notch filters; determine eight intermediate total delays associated with chaining the three hypothetical first-order notch filters together; sort the eight intermediate total delays in ascending order; determine seven delay differences by subtracting, for respective ones of the eight intermediate total delays except for a lowest intermediate delay, the intermediate total delays from immediately subsequent ones of the intermediate total delays; and select the delays associated with the delay elements to be the respective delay differences.

Example 9: The apparatus according to any one of Examples 1-8, wherein the delay elements are electrically connected in series.

Example 10: A method of generating a reduced slew rate signal, the method comprising: delaying a received signal to generate delayed signals using delays chosen to reduce emissions of one or more predetermined frequencies of the reduced slew rate signal as compared to the received signal; and combining the delayed signals to generate the reduced slew rate signal at an output terminal.

Example 11: The method of Example 10, wherein combining the delayed signals comprises driving, with sub-drivers, the delayed signals to summing circuitry electrically connected to the output terminal.

Example 12: The method according to any one of Examples 10 and 11, comprising selecting the delays using delay control circuitry electrically connected to delay elements associated with the delays.

Example 13: The method of Example 12, wherein selecting the delays using delay control circuitry electrically connected to delay elements associated with the delays, comprises: determining three different preliminary delays associated with three predetermined frequencies for three hypothetical first-order notch filters; determining eight intermediate total delays associated with chaining the three hypothetical first-order notch filters together; sorting the eight intermediate total delays in ascending order; determining seven delay differences by subtracting, for respective ones of the eight intermediate total delays except for a lowest intermediate delay, the intermediate total delays from immediately subsequent ones of the intermediate total delays; and selecting the delays associated with the delay elements to be the delay differences.

Example 14: A system, comprising: a shared transmission medium of a wired local area network; an encoder to provide a signal to be transmitted to the wired local area network via the shared transmission medium; and a variable delay driver comprising: an input terminal to receive the signal from the encoder; delay elements to generate delayed signals responsive to the received signal, delays associated with respective ones of the delay elements chosen to reduce emissions of one or more predetermined frequencies of a reduced slew rate signal as compared to the received signal; combination circuitry to combine the delayed signals to generate the reduced slew rate signal; and an output terminal electrically connected to the shared transmission medium, the output terminal to deliver the reduced slew rate signal to the shared transmission medium.

Example 15: The system of Example 14, comprising a vehicle including the shared transmission medium, the vehicle including endpoints electrically connected to the shared transmission medium, at least one of the endpoints including the encoder and the variable delay driver.

Example 16: The system of Example 15, wherein the one or more predetermined frequencies include one or more operating frequencies of one or more devices operating in the vehicle.

### CONCLUSION

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, etc.) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different sub-combinations of some of the elements. For example, the phrase “A, B, C, D, or combinations thereof” may refer to any one of A, B, C, or D; the combination of each of A, B, C, and D; and any sub-combination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one examples may be combined with features of another example while still being encompassed within the scope of the invention as contemplated by the inventor.

What is claimed is:

1. An apparatus, comprising:
an input terminal to receive a signal;
delay elements electrically connected to the input terminal, the delay elements to provide delayed signals responsive to the received signal, respective delayed signals including delayed versions of the received signal;
an output terminal to provide a reduced slew rate signal; and
combination circuitry electrically connected to the delay elements and the output terminal, the combination circuitry to combine the delayed signals to generate the reduced slew rate signal, delays associated with the delay elements chosen to reduce emissions of one or more predetermined frequencies of the reduced slew rate signal as compared to the received signal.

2. The apparatus of claim 1, wherein the combination circuitry includes sub-drivers, at least some of the sub-drivers electrically connected to drive respective ones of the delayed signals to the output terminal.

3. The apparatus of claim 2, wherein one of the sub-drivers is electrically connected from the input terminal to the output terminal.

4. The apparatus of claim 2, wherein at least one of the sub-drivers includes:
a pull-up current source electrically connected to a power supply high voltage potential node;
a pull-down current source electrically connected to a power supply low voltage potential node; and
a complementary metal oxide semiconductor (CMOS) inverter electrically connected from the pull-up current source to the pull-down current source.

5. The apparatus of claim 4, wherein a pull-up current supplied by the pull-up current source is substantially the same as a pull-down current supplied by the pull-down current source.

6. The apparatus of claim 1, wherein the combination circuitry includes summing circuitry to combine the delayed signals by adding the delayed signals.

7. The apparatus of claim 1, comprising delay control circuitry electrically connected to the delay elements, the delay control circuitry to provide delay control signals to the delay elements to control the delays associated with the delay elements.

8. The apparatus of claim 7, wherein:
the one or more predetermined frequencies include three predetermined frequencies; and
the delay control circuitry to:
determine three different preliminary delays associated with the three predetermined frequencies for three hypothetical first-order notch filters;
determine eight intermediate total delays associated with chaining the three hypothetical first-order notch filters together;
sort the eight intermediate total delays in ascending order;
determine seven delay differences by subtracting, for respective ones of the eight intermediate total delays except for a lowest intermediate delay, the intermediate total delays from immediately subsequent ones of the intermediate total delays; and
select the delays associated with the delay elements to be the respective delay differences.

9. The apparatus of claim 1, wherein the delay elements are electrically connected in series.

10. A method of generating a reduced slew rate signal, the method comprising:
delaying a received signal to generate delayed signals using delays chosen to reduce emissions of one or more predetermined frequencies of the reduced slew rate signal as compared to the received signal; and
combining the delayed signals to generate the reduced slew rate signal at an output terminal.

11. The method of claim 10, wherein combining the delayed signals comprises driving, with sub-drivers, the delayed signals to summing circuitry electrically connected to the output terminal.

12. The method of claim 10, comprising selecting the delays using delay control circuitry electrically connected to delay elements associated with the delays.

13. The method of claim 12, wherein selecting the delays using delay control circuitry electrically connected to delay elements associated with the delays, comprises:
determining three different preliminary delays associated with three predetermined frequencies for three hypothetical first-order notch filters;
determining eight intermediate total delays associated with chaining the three hypothetical first-order notch filters together;
sorting the eight intermediate total delays in ascending order;
determining seven delay differences by subtracting, for respective ones of the eight intermediate total delays except for a lowest intermediate delay, the intermediate total delays from immediately subsequent ones of the intermediate total delays; and
selecting the delays associated with the delay elements to be the delay differences.

14. A system, comprising:
a shared transmission medium of a wired local area network;
an encoder to provide a signal to be transmitted to the wired local area network via the shared transmission medium; and
a variable delay driver comprising:
an input terminal to receive the signal from the encoder;
delay elements to generate delayed signals responsive to the received signal, delays associated with respective ones of the delay elements chosen to reduce emissions of one or more predetermined frequencies of a reduced slew rate signal as compared to the received signal;
combination circuitry to combine the delayed signals to generate the reduced slew rate signal; and
an output terminal electrically connected to the shared transmission medium, the output terminal to deliver the reduced slew rate signal to the shared transmission medium.

15. The system of claim 14, comprising a vehicle including the shared transmission medium, the vehicle including endpoints electrically connected to the shared transmission medium, at least one of the endpoints including the encoder and the variable delay driver.

16. The system of claim 15, wherein the one or more predetermined frequencies include one or more operating frequencies of one or more devices operating in the vehicle.
